(19) United States
(12) Patent Application Publication
(10) Pub. No.: US 2002/0151155 A1
(43) Pub. Date: Oct. 17, 2002

(54) Reflector wire structure and method for manufacturing the same

(76) Inventor: Yueh Ching, Taipei (TW)

Correspondence Address: J.C. Patents, Inc., 4 Venture, Suite 250, Irvine, CA, 92618, US

(21) Appl. No.: 09/835,015

(22) Filed: Apr. 13, 2001

(51) Int. Cl. H01L 21/425

(52) U.S. Cl. 438/530; 438/536

(57) ABSTRACT

A structure of a reflector is disclosed. Accordingly the present invention provides a reflector wire structure comprising, an electrical wire having a covering layer formed thereon. A base film is formed over the covering layer. A retroreflective film is formed over the base film. A protective film is formed over the retroreflective film.

### BACKGROUND OF THE INVENTION

1. Field of Invention

The present invention relates generally to safety device and more specifically to a reflector wire structure and a method for manufacturing the same.

2. Description of Related Art

Electrical wires are used for connecting the electronic devices such as lamps, expensive electronics devices like personal computers, televisions, washers, driers, expensive instruments used in quality assurance such as high-performance-liquid-chromatography, infra-red scanners, UV scanners, mass spectroscope, just to name some, to the power source and a switching device for turning on/off of power supply.

Recently, in an electronic apparatus or an electrical facility, the large number of electrical wires connecting the corresponding terminals tends to be relatively large as circuit wiring is formed in a higher density and in a more complex manner. Consequently, during maintenance or trouble shooting, it is very difficult to isolate a specific wire connecting from one terminal to the other terminal. Even though some endeavored using colored wiring to differentiate them but due to their poor visibility in maintenance areas such as inside false ceiling, control panels, darker basement, dark control rooms, during power outages for maintenance, it is very difficult to differentiate them from each other. Therefore it is highly desirable and also critical to improve the visibility of electrical wires, power switch boards, power plugs and sockets that control the electronic devices power supply.

Whenever a blackout is experienced for example, due to explosion of fuses, or explosion of transformer, or voluntary power supply outages controlled by the power supply sources and every time when the power is restored, there will be a sudden power surge, even higher voltages than usual is experienced for few seconds, immediately after the power is restored, this may lead to shorting of the electronic devices due to sudden high voltage power surge or when the devices are subjected to a long term power outages under unprotected conditions will degrade the quality and reliability of the electrical devices. It could be extremely dangerous when the motors that drive the moving parts in the construction sites are suddenly turned on when the power is restored. However this problem can be overcome by turning off the electronic devices whenever there is a power outage and then turning them back on once the voltage in the power supply is stabilized, after the power supply has been restored. Usually, the power supply voltages will be stabilized after 5-10 minutes after the power has been restored. However one problem is, in the event of a power failure, the nighttime visibility of the power switches and electric wire which are used for connecting the expensive and sensitive electronic devices is very poor. Therefore this makes it very difficult to locate the electric wire, power switch, and electrical wire plugs or sockets that controls the expensive electronic devices power source under poor visibility. Therefore it is highly desirable and also critical to improve the nighttime visibility of electrical wires, power switch boards, power plugs and sockets that control the electronic devices power supply.

Accordingly, the present invention provides a solution to improve the visibility of the electrical wire.

### SUMMARY OF THE INVENTION

The present invention provides a structure of a reflector wire which has high nighttime visibility, and a method for manufacturing the same.

The present invention provides a structure of a reflector wire with highly improved visibility so that the reflector wire can be very easily visible in daytime, nighttime or anytime.

Accordingly the present invention provides a reflector wire structure comprising, an electrical wire having a covering layer formed thereon. A base film is formed on the covering layer. A retroreflective film is formed on the base film. A protective film is formed over the retroreflective film.

It is to be understood by those skilled in the art that because the retroreflective material is formed on the electrical wire, therefore the daytime and the nighttime visibility of the electrical wire can be substantially improved.

It is to be understood by those skilled in the art that the reflector wire is highly visible in day light when illuminated with natural light. It is also highly visible at night when illuminated with a flash light. It is also fairly visible even in a limited visible light during a power outage. This in turn makes it possible to easily and quickly locate the reflector wire, the power source outlets such as sockets and power switch to which the reflector wire is connected in the event of power outages. Therefore electric hazard due to power outages can be effectively prevented.

It is to be further understood by those skilled in the art that when visible light source is incident on the reflector wire, the reflector wire will appear brighter. Therefore when the power outage result in a total darkness, a flash light may be used to easily locate the reflector wire.

### BRIEF DESCRIPTION OF THE DRAWINGS

FIGS. 1A through 1C shows a schematic, cross sectional view showing the manufacturing process of a reflector wire according to the first preferred embodiment of the present invention.

FIG. 2 shows a schematic, cross sectional view showing the structure of a reflector wire according to the second preferred embodiment of the present invention.

FIGS. 3 through 5 shows a schematic cross sectional view showing the construction of retroreflective films.

FIG. 6 shows a schematic view showing the structure of an electrical extension reflector wire according to the third preferred embodiment of the present invention.

FIG. 7 shows a schematic view showing the structure of reflector socket according to the fourth preferred embodiment of the present invention.

FIG. 8 shows a schematic view showing the structure of an electrical plug according to the fifth preferred embodiment of the present invention.

### DESCRIPTION OF THE PREFERRED EMBODIMENTS

Reference will be made in detail to the present preferred embodiments of the invention, examples of which are illustrated in the accompanying drawings. Wherever possible, the same reference numbers are used in the drawings and the description to refer to the same or like parts.

It is to be understood that the foregoing general description and the following detailed description are exemplary, and are intended to provide further explanation of the invention as claimed.

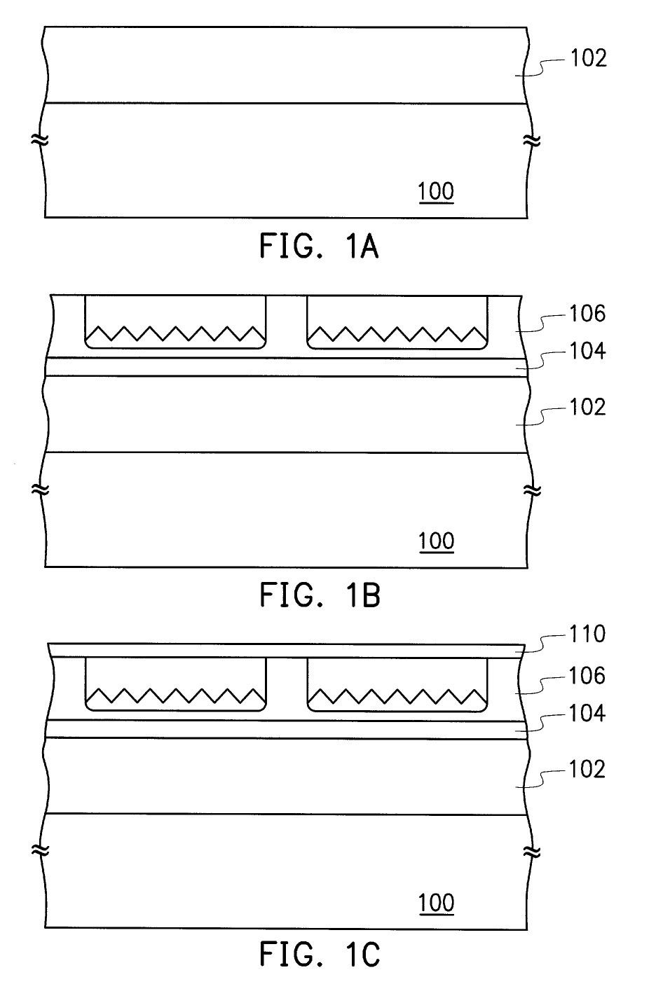

Referring to FIG. 1A, according to the first preferred embodiment of the present invention, a reflector wire structure comprising, an electrical wire 100 having a covering layer 102 formed thereon. The material of the electrical wire preferably is made of aluminum or a copper material. The material of the covering layer 102 preferably made of a poly-vinyl-chloride (PVC), polyurethanes, or nylon. The covering layer 102 is formed preferably by performing an extrusion process.

Referring to FIG. 1B, a base film 104 and a retroreflective film 106 are formed over the covering layer 102.

The material of the base film 104 is preferably selected from a group consisting of an adhesive material, a barrier film with an adhesive and a barrier layer without an adhesive. The material of the barrier film is preferably selected from a group consisting of polyurethane, ethylene methyl acrylate copolymer, ethylene N-butyl acrylate copolymer, ethylene ethyl acrylate copolymer, ethylene vinyl acetate copolymer, polymerically plasticized PVC, and polyurethane primed ethylene acrylic acid copolymer.

The material of the retroreflective film 106 is preferably selected from a group consisting of acrylic polymers such as plymethylmethacrylate, polycarbonates, cellulosics, polyesters such as polybutyeleneterephthalate, polyethyleneterephthalate, fluoropolymers, polamides, polyetherketones, polyetherimide, polyoelfins, polystyrene co-polymerspolysuphones, urethanes, and mixture of the above polymers such as polyester and polycarbonate blend, and a fluoropolymer and acrylic polymer blend, and commercially available Scotchlite Engineer Grade, High Intensity Grade, Diamond Grade LDP, and Diamond Grade VIP material, manufactured by Minnesota Mining and Manufacturing Co. (3M). Additional materials suitable for forming the retroreflective films include reactive resin systems capable of being cross linked by free radical polymerization mechanism by exposure to actinic radiation, for example, electron beam, ultraviolet light, or visible light. Additionally, these materials may be polymerized by thermal means with addition of a thermal initiator such as benzoyl peroxide. Radiation initiated cationic polymerizable resins also may be used. Reactive resins suitable for forming the retroreflective films may include blends of photoinitiator and at least one compound bearing an acrylate group. Preferably the resin blend contains a monofunctional, a difunctional, or a polyfunctional compound to ensure formation a cross linked polymeric network upon irradiation.

The retroreflective films 106 constructions are generally divided into three categories.

One, An enclosed lens glass beaded type consisting essentially of a transparent film 206 backed with glass beads 204, wherein the glass beads 204 are formed in a spacer film 202, and reflective aluminized film 200 is formed beneath the spacer film 202. The glass beads 204 focus the incident light on the aluminized film 200. This structure is shown in FIG. 3.

Two, an encapsulated glass beaded type, consist essentially the construction similar to the enclosed leans glass beaded film but instead of glass beads 204 being in direct contact with the surface of the top film 206, there is an air interface 205. The improved refraction of light passing from air into the glass enables the focusing to take place at the back of the glass bead 200. Thus the need for a spacer coat between the beads and the aluminized film is eliminated. This structure results in more efficient retroreflection of the incident light enabling the film to appear brighter when illuminated. This structure is shown in FIG. 4.

Three, cube corner type, consist essentially the construction similar to the encapsulated glass beaded film but instead of glass beads, glass cubes 208 are used and is being in direct contact with the surface of the top film 206, there is an air interface 205. The improved refraction of light passing from air into the glass cubes enables the focusing to take place at the surface of the glass cube 208. Thus the need for a spacer coat between the beads and the aluminized film is eliminated. The physics of design of cube corner retroreflectors make them most efficient and they provide the brightest type of retroreflective films 106. A significant characteristic of this design is that metalization is not required, although it may be used. Normally there is an air interface to the cube corners. This structure is shown in FIG. 5.

Both the encapsulated glass bead and the cube corner designs are similar in that they have air interfaces. This air interface must be protected against contact from water in order to maintain its efficiency. This is normally accomplished by dividing the surface into small segments of a design that will isolate one segment from another. In the event of mechanical failure of one segment resulting in water intrusion, the entire surface is not destroyed. Protection of the air interface is normally accomplished by bonding a secondary film to the perimeters of the design separating one segment from another.

The bonding of the covering layer 102, the base film 104 comprising an adhesive material and the retroreflective film 106 is accomplished by pressing the retroreflective film 106 and the base film 104 against the covering layer 102. When the base film 104 comprises only a barrier film without an adhesive material, then the bonding or welding of covering layer 102, the base film 104 and the retroreflective film 106 is accomplished by using a thermal or radio frequency energies.

During the thermal welding process, the heating element is positioned between the retroreflective film 106, the barrier film and the covering layer 102, preferably the without being in contact with either, and then the retroreflective film 106 by the heating element and pass between pressure rollers after being heated such that a bond between the retroreflective film 106, the barrier film and the covering layer 102 develops. The heating element is preferably heated to a temperature of about 460° C. Alternatively, a hot air may be used instead of heating element.

During the radio frequency welding process, appropriate radio frequency energies is delivered through antennas mounted within appropriate platens that are pressed onto the appropriate surfaces of the retroreflective film 106, barrier film and the covering layer 102 applying appropriate amount of pressure and for an appropriate duration of time. The frequency of the radio frequency energy and the field strength are variable by the operator and chosen for suitability dependent upon the polymeric components within the retroreflective film 106, barrier film and the covering layer 102.

Referring to FIG. 1C, a protective film 110 is coated over the resulting structure. Thus a reflector wire 120 is manufactured.

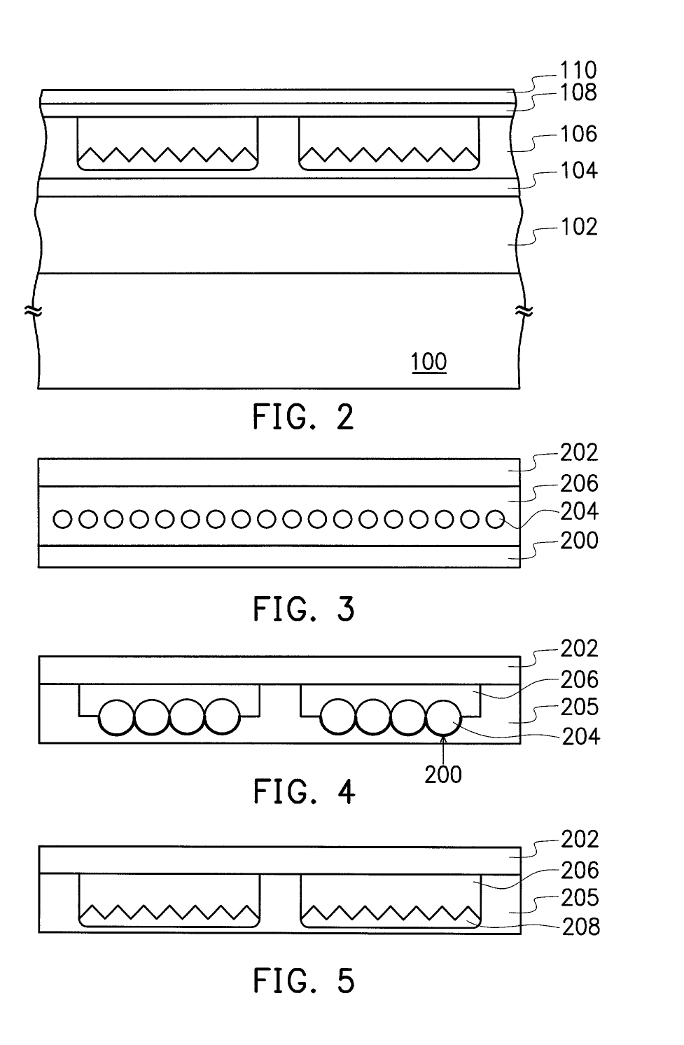

Referring to FIG. 2, the second preferred embodiment of the present invention is similar to the first preferred embodiment except that an additional fluorescent film 108 is formed over the retroreflective film 106 instead of a protective film 110. An optional is that the protective film 110 may be formed over the fluorescent film 108. The advantage of the second embodiment is that the visibility of the reflector wire is further improved due to both reflector and fluorescent effects. The bonding of the fluorescent film 108 onto to the retrorflector film 106 essentially consist of coating a reflective coating 107 on the retroreflective film 106 and then pressing the fluorescent film 108 against the retroreflective film 106 and removing the release paper 10 which is loosely adhered thereto. The material of the flurorescent film 108 essentially consisting of a dye composite material of an ever tacky adhesive and a release paper 10 is then loosely adhered thereon. The dye composition comprises a transparent fluorescent dye which fluoresces light of one wavelength band and transmits light of another wave length. These dye include rhodamine B extra (violet color) and rhodamine 6DGN (red color) and fluorescein dyes. Any of the transparent fluorescent dyes may be mixed with other transparent dyes (whether fluorescent or not) to produce a transparent fluorescent dye composition having desired colors and other desired properties.

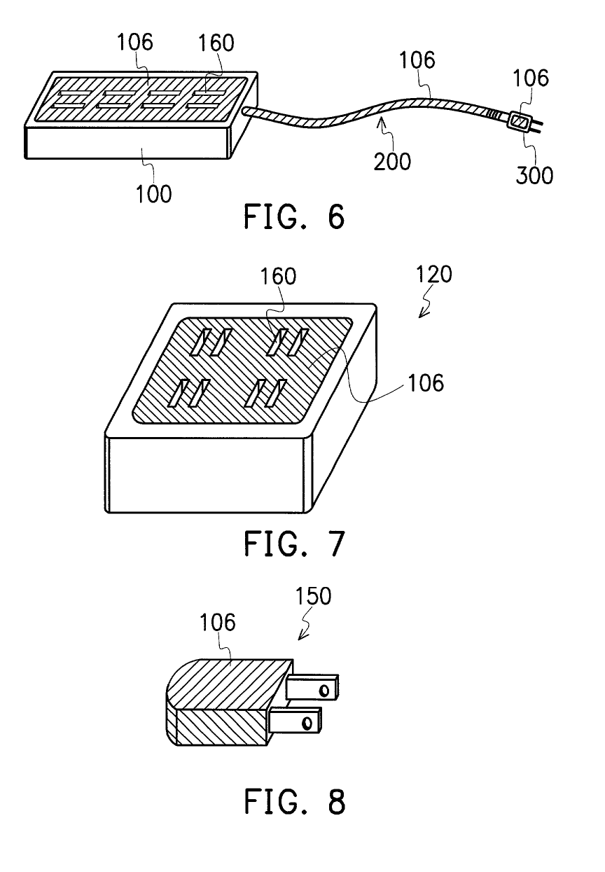

Referring to FIG. 6, showing the third preferred embodiment of the present invention, wherein an extension electrical wire comprising a socket structure 100 having a group of female outlet switches 160 at one end of an electrical wire 200 and a plug 300 on the other end, wherein the retroreflective film 106 is welded over the socket structure 100, the electrical wire 200 and the plug 300, by following the steps of manufacture as described under the first and second preferred embodiments.

Referring to FIG. 7, showing the fourth preferred embodiment of the present invention, wherein a socket structure 120 comprising a group of female outlet switches 160, wherein the retroreflective film 106 is welded over the socket structure 120, by following the steps of manufacture as described under the first and second preferred embodiments.

Referring to FIG. 8, showing the fifth preferred embodiment of the present invention, wherein an electrical plug structure 150, wherein the retroreflective film 106 is welded over the plug structure 150, by following the steps of manufacture as described under the first and second preferred embodiments.

It is to be understood by those skilled in the art that because the retroreflective film 106 is formed over the electrical wire, therefore the daytime and the nighttime visibility of the electrical wire can be substantially improved.

It is to be understood by those skilled in the art that the reflector wire is highly visible in day light when illuminated with natural light. The reflector wire is also highly visible at night when illuminated with a flash light. It is also fairly visible even in a limited visible light during a power outage. Therefore it is possible to easily and quickly locate the reflector wire, the power source outlets such as sockets and power switch to which the electrical wire is connected in the daytime, nighttime or even during of power outages in the daytime or the nighttime or anytime. Therefore electric hazard due to power outages can be effectively prevented.

It is to be further understood by those skilled in the art that when visible light source is incident on the reflector wire, the reflector wire will appear brighter. Therefore when the power outage result in a total darkness, a flash light may be used to easily locate the reflector wire.

It is to be further understood by those skilled in the art that the reflector wire can be designed have different colors so that they could easily differentiated from each other.

While the invention has been described in conjunction with a specific best mode, it is to be understood that many alternatives, modifications, and variations will be apparent to those skilled in the art in light of the a foregoing description. Accordingly, it is intended to embrace all such alternatives, modifications, and variations which fall within the spirit and scope of the included claims. All matters set forth herein or shown in the accompanying drawings are to be interpreted in an illustrative and non-limiting sense.

What is claimed is:

1. A composite reflector wire structure, the structure comprising:
a substrate provided;
a base film formed over the substrate;
a retroreflective film formed over the base film; and
a glass coating film formed over the reflective layer.

2. The structure according to claim 1, wherein the material of the retroreflective film is selected from a group consisting acrylic polymers such as plymethylmethacrylate, polycarbonates, cellulosics, polyesters such as polybutyeleneterephthalate, polyethyleneterephthalate, fluoropolymers, polamides, polyetherketones, polyetherimide, polyoelfins, polystyrene co-polymerspolysuphones, urethanes, and mixture of the above polymers such as polyester and polycarbonate blend, and a fluoropolymer and acrylic polymer blend, and commercially available Scotchlite Engineer Grade, High Intensity Grade, Diamond Grade LDP, and Diamond Grade VIP.

3. The structure according to claim 1, wherein the retroreflective film comprises additional materials, wherein the additional material include reactive resin systems capable of being cross linked by free radical polymerization mechanism by exposure to actinic radiation, for example, electron beam, ultraviolet light, or visible light.

4. The structure according to claim 1, wherein the material of the base film is selected from a group consisting of an adhesive material, a barrier film with an adhesive material, and a barrier layer without an adhesive material.

5. The structure according to claim 4, wherein the substrate, the adhesive material, and the retroreflective film are bonded together by placing the adhesive material in between substrate and the retroreflective film and pressing the retroreflective film against the substrate.

6. The structure according to claim 4, wherein the material of the barrier film is selected from a group consisting polyurethane, ethylene methyl acrylate copolymer, ethylene N-butyl acrylate copolymer, ethylene ethyl acrylate copolymer, ethylene vinyl acetate copolymer, polymerically plasticized PVC, and polyurethane primed ethylene acrylic acid copolymer.

7. The structure according to claim 4, wherein the substrate, the barrier film without an adhesive material and the retroreflective film are welded simultaneously by using a thermal energy.

8. The structure according to claim 4, wherein the substrate, the barrier film without an adhesive material and the retroreflective film are welded simultaneously by using radio frequency energy.

9. The structure according to claim 1, wherein the retroreflective film has a high daytime and nighttime visibility.

10. The structure according to claim 1, wherein the substrate is selected from a group consisting of an electrical wire, an electrical extension wire include a socket structure comprising a group of female outlet switches, an electrical socket and an electrical plug.

11. The structure according to claim 1, wherein exposed portions of the substrate includes an insulating layer, wherein the material of the insulating layer is selected from a group consisting of an polyvinyl chloride, polyurethanes and nylon.

12. A composite reflector wire structure, the structure comprising:
a substrate provided;
a base film formed over the substrate;
a retroreflective film formed over the base film;
a fluorescent film formed over the retroreflective film; and
a glass coating film formed over the reflective layer.

13. The structure according to claim 12, wherein the fluorescent film comprises a dye composite material, wherein the dye composite material comprises a transparent fluorescent dye which fluoresces light of one wavelength band and transmits light of another wave length.

14. The structure according to claim 12, wherein the dye composite material include rhodamine B extra (violet color) and rhodamine 6DGN (red color) and fluorescein dyes, and any of the transparent fluorescent dyes may be mixed with other transparent dyes (whether fluorescent or not) to produce a transparent fluorescent dye composition having desired colors and other desired properties.

15. The structure according to claim 12, wherein the material of the retroreflective film is selected from a group consisting acrylic polymers such as plymethylmethacrylate, polycarbonates, cellulosics, polyesters such as polybutyeleneterephthalate, polyethyleneterephthalate, fluoropolymers, polamides, polyetherketones, polyetherimide, polyoelfins, polystyrene co-polymerspolysuphones, urethanes, and mixture of the above polymers such as polyester and polycarbonate blend, and a fluoropolymer and acrylic polymer blend, and commercially available Scotchlite Engineer Grade, High Intensity Grade, Diamond Grade LDP, and Diamond Grade VIP

16. The structure according to claim 12, wherein the retroreflective film comprises additional materials, wherein the additional material include reactive resin systems capable of being cross linked by free radical polymerization mechanism by exposure to actinic radiation, for example, electron beam, ultraviolet light, or visible light.

17. The structure according to claim 12, wherein the material of the base film is selected from a group consisting of an adhesive material, a barrier film with an adhesive material, and a barrier layer without an adhesive material.

18. The structure according to claim 17, wherein the substrate, the adhesive material, and the retroreflective film are bonded together by placing the adhesive material in between substrate and the retroreflective film and pressing the retroreflective film against the substrate.

19. The structure according to claim 17, wherein the material of the barrier film is selected from a group consisting polyurethane, ethylene methyl acrylate copolymer, ethylene N-butyl acrylate copolymer, ethylene ethyl acrylate copolymer, ethylene vinyl acetate copolymer, polymerically plasticized PVC, and polyurethane primed ethylene acrylic acid copolymer.

20. The structure according to claim 17, wherein the substrate, the barrier film without an adhesive material and the retroreflective film are welded simultaneously by using a thermal energy.

21. The structure according to claim 17, wherein the substrate, the barrier film without an adhesive material and the retroreflective film are welded simultaneously by using radio frequency energy.

22. The structure according to claim 12, wherein the retroreflective film has a high daytime and nighttime visibility.

23. The structure according to claim 12, wherein the substrate is selected from a group consisting of an electrical wire, an electrical extension wire include a socket structure comprising a group of female outlet switches, an electrical socket and an electrical plug.

24. The structure according to claim 12, wherein exposed portions of the substrate includes an insulating layer, wherein the material of the insulating layer is selected from a group consisting of an polyvinyl chloride, polyurethanes and nylon.

25. A method for manufacturing a composite reflector wire structure, the method comprising:
providing a substrate;
forming a base film over the substrate;
forming a retroreflective film over the base film; and
forming a glass coating film over the reflective layer.

26. The method according to claim 25, wherein the material of the retroreflective film is selected from a group consisting acrylic polymers such as plymethylmethacrylate, polycarbonates, cellulosics, polyesters such as polybutyeleneterephthalate, polyethyleneterephthalate, fluoropolymers, polamides, polyetherketones, polyetherimide, polyoelfins, polystyrene co-polymerspolysuphones, urethanes, and mixture of the above polymers such as polyester and polycarbonate blend, and a fluoropolymer and acrylic polymer blend, and commercially available Scotchlite Engineer Grade, High Intensity Grade, Diamond Grade LDP, and Diamond Grade VIP.

27. The method according to claim 25, wherein the retroreflective film comprises additional materials, wherein the additional material include reactive resin systems capable of being cross linked by free radical polymerization mechanism by exposure to actinic radiation, for example, electron beam, ultraviolet light, or visible light.

28. The method according to claim 25, wherein the material of the base film is selected from a group consisting of an adhesive material, a barrier film with an adhesive material, and a barrier layer without an adhesive material.

29. The method according to claim 28, wherein the substrate, the adhesive material, and the retroreflective film are bonded together by placing the adhesive material in between substrate and the retroreflective film and pressing the retroreflective film against the substrate.

30. The method according to claim 28, wherein the material of the barrier film is selected from a group consisting polyurethane, ethylene methyl acrylate copolymer, ethylene N-butyl acrylate copolymer, ethylene ethyl acrylate copolymer, ethylene vinyl acetate copolymer, polymerically plasticized PVC, and polyurethane primed ethylene acrylic acid copolymer.

31. The method according to claim 28, wherein the substrate, the barrier film without an adhesive material and the retroreflective film are welded simultaneously by using a thermal energy.

32. The method according to claim 28, wherein the substrate, the barrier film without an adhesive material and the retroreflective film are welded simultaneously by using radio frequency energy.

33. The method according to claim 25, wherein the retroreflective film has a high daytime and nighttime visibility.

34. The method according to claim 25, wherein the substrate is selected from a group consisting of an electrical wire, an electrical extension wire include a socket structure comprising a group of female outlet switches, an electrical socket and an electrical plug.

35. The method according to claim 25, wherein exposed portions of the substrate includes an insulating layer, wherein the material of the insulating layer is selected from a group consisting of an polyvinyl chloride, polyurethanes and nylon.
